(19) United States
(12) Patent Application Publication
(10) Pub. No.: US 2012/0134426 A1
(43) Pub. Date: May 31, 2012

(54) METHOD AND APPARATUS FOR REUSING TREE STRUCTURES TO ENCODE AND DECODE BINARY SETS

(75) Inventors: Joel Sole, La Jolla, CA (US); Peng Yin, Ithaca, NY (US); Xiaoan Lu, Princeton, NJ (US); Yunfei Zheng, San Diego, CA (US); Qian Xu, Foisom, CA (US)

(73) Assignee: THOMSON LICENSING, Issy Les Moulineauz (FR)

(21) Appl. No.: 13/390,994

(22) PCT Filed: Aug. 12, 2010
(86) PCT No.: PCT/US10/02228

§ 371 Date: Feb. 17, 2012

Related U.S. Application Data
(60) Provisional application No. 61/235,442, filed on Aug. 20, 2009.

(51) Int. Cl. H04N 7/26; H03M 7/00

(52) U.S. Cl. 375/240.25; 375/240.01; 341/79; 375/E07.026; 375/E07.027

(57) ABSTRACT

Methods and apparatus are provided for reusing tree structures to encode and decode binary sets. The method encodes a binary set of data using a tree structure, wherein said encoding step encodes a portion of the binary set using a portion of the tree structure and encodes another portion of the binary set by reusing at least some of the portion of the tree structure used to encode the portion of the binary set.

### CROSS-REFERENCE TO RELATED APPLICATIONS

This application claims the benefit of U.S. Provisional Application Ser. No. 61/235,442, filed Aug. 20, 2009 (Attorney Docket No. PU090109), which is incorporated by reference herein in its entirety.

### TECHNICAL FIELD

The present principles relate generally to video encoding and decoding and, more particularly, to methods and apparatus for reusing tree structures to encode and decode binary sets.

### BACKGROUND

The block-based discrete transform is a fundamental component of many image and video compression standards including, for example, the Joint Photographic Experts Group, the International Telecommunication Union, Telecommunication Sector (ITU-T) H.263 Recommendation (hereinafter the “H.263 Recommendation”), the International Organization for Standardization/International Electrotechnical Commission (ISO/IEC) Moving Picture Experts Group-1 (MPEG-1) Standard, the ISO/IEC MPEG-2 Standard, the ISO/IEC MPEG-4 Part 10 Advanced Video Coding (AVC) Standard/ITU-T H.264 Recommendation (hereinafter the “MPEG-4 AVC Standard”), as well as others, and is used in a wide range of applications. Most modern video coding standards employ transforms to efficiently reduce the correlation of the residue in the spatial domain. The discrete cosine transform (DCT) is the most extensively used block transform.

After transformation, the transform coefficients are then encoded. A common way to encode the transform coefficients involves two steps. In a first step, the location of the non-zero coefficients is encoded. In a second step, the level and sign of the non-zero coefficients are encoded. Regarding the first step, an efficient way to encode the location involves using tree structures. However, each tree requires storing and updating probabilities for its nodes and leaves. Video coding techniques are improving performance by increasing the prediction and transform sizes. These larger sizes have an impact on the requirements of the trees structures.

After the transform process, the transform coefficients are quantized. Then, the quantized coefficients are entropy encoded to convey the information of their level and sign. The percentage of zeroed coefficients is very high, so the encoding process is efficient when divided into two steps as described above.

Sending the location of the coefficients can still be quite expensive, because the video content data has varying statistics and properties, and also because the respective significances of the transform coefficients have different properties depending on the positions of the respective coefficients. Tree-based encoding of the significance works well, but can increase the amount of probabilities that need to be tracked during the encoding and decoding process.

For example, transforms of size 16×16 have 256 coefficients. If a binary tree is employed to encode the significance map, then this tree has 255 inner nodes and 256 leaves. In a typical implementation using an arithmetic coder, the encoding of the tree involves two probabilities for each inner node, that is, 510 probabilities to be updated by the encoder and decoder. This number of probabilities is quite high, and will be even higher considering that larger transforms of size 32×32 and 64×64 are used for the highest video resolutions.

### SUMMARY

These and other drawbacks and disadvantages of the prior art are addressed by the present principles, which are directed to methods and apparatus for reusing tree structures to encode and decode binary sets.

According to an aspect of the present principles, an apparatus is provided. The apparatus includes an encoder for encoding a binary set of data using a tree structure. The encoder encodes a portion of the binary set using a portion of the tree structure and encodes another portion of the binary set by reusing at least some of the portion of the tree structure used to encode the portion of the binary set.

According to another aspect of the present principles, a method in a video encoder is provided. The method includes encoding a binary set of data using a tree structure. The encoding step encodes a portion of the binary set using a portion of the tree structure and encodes another portion of the binary set by reusing at least some of the portion of the tree structure used to encode the portion of the binary set.

According to yet another aspect of the present principles, there is provided an apparatus. The apparatus includes a decoder for decoding a binary set of data using a tree structure. The decoder decodes a portion of the binary set using a portion of the tree structure and decodes another portion of the binary set by reusing at least some of the portion of the tree structure used to decode the portion of the binary set.

According to a further aspect of the present principles, there is provided a method in a video decoder. The method includes decoding a binary set of data using a tree structure. The decoding step decodes a portion of the binary set using a portion of the tree structure and decodes another portion of the binary set by reusing at least some of the portion of the tree structure used to decode the portion of the binary set.

These and other aspects, features and advantages of the present principles will become apparent from the following detailed description of exemplary embodiments, which is to be read in connection with the accompanying drawings.

### BRIEF DESCRIPTION OF THE DRAWINGS

The present principles may be better understood in accordance with the following exemplary figures, in which:

FIG. 1 is a block diagram showing an exemplary video encoder to which the present principles may be applied, in accordance with an embodiment of the present principles;

FIG. 2 is a block diagram showing an exemplary video decoder to which the present principles may be applied, in accordance with an embodiment of the present principles;

FIG. 3 is a diagram showing an exemplary tree-structure to which the present principles may be applied, in accordance with an embodiment of the present principles;

FIG. 4 is a diagram showing an exemplary binary tree to which the present principles may be applied, in accordance with an embodiment of the present principles;

FIG. 5 is a diagram showing an exemplary mapping of a binary set to the leaves of a binary tree;

FIG. 6 is a diagram showing an exemplary encoding of a binary set using a binary zero-tree;

FIG. 7 is a diagram showing an exemplary mapping of two-dimensional (2-D) coefficients to a one dimensional (1-D) binary set;

FIG. 8 is a diagram showing parts of the exemplary mapping of FIG. 7 that can share the same tree, in accordance with an embodiment of the present principles;

FIG. 9 is a diagram showing other parts of the exemplary mapping of FIG. 7 that can share the same tree structure and probabilities in accordance with an embodiment of the present principles;

FIG. 10 is a diagram showing an exemplary recursive binary tree, in accordance with an embodiment of the present principles;

FIG. 11 is a diagram showing an exemplary re-use of smaller trees to create a larger tree for binary sets in accordance with an embodiment of the present principles;

FIG. 12 is a flow diagram showing an exemplary method for reusing tree structures to encode a binary set in accordance with an embodiment of the present principles;

FIG. 13 is a flow diagram showing an exemplary method for reusing tree structures to decode a binary set in accordance with an embodiment of the present principles;

FIG. 14 is a flow diagram showing another exemplary method for reusing tree structures to encode a binary set in accordance with an embodiment of the present principles;

FIG. 15 is a flow diagram showing another exemplary method for reusing tree structures to decode a binary set in accordance with an embodiment of the present principles;

FIG. 16 is a flow diagram showing still another exemplary method for reusing tree structures to encode a binary set in accordance with an embodiment of the present principles;

FIG. 17 is a flow diagram showing still another exemplary method for reusing tree structures to decode a binary set in accordance with an embodiment of the present principles;

FIG. 18 is a flow diagram showing yet another exemplary method for reusing tree structures to encode a binary set in accordance with an embodiment of the present principles; and

FIG. 19 is a flow diagram showing yet another exemplary method for reusing tree structures to decode a binary set in accordance with an embodiment of the present principles.

### DETAILED DESCRIPTION

The present principles are directed to methods and apparatus for reusing tree structures to encode and decode binary sets. It is to be appreciated that the present principles can be applied to binary sets relating to any type of underlying data. Thus, some exemplary types of data to which a binary set can apply and which can be utilized in accordance with the present principles include, but are not limited to, images, video, acoustics (e.g., voice, music, sounds, etc.), and so forth. It is emphasized that the preceding list is merely illustrative and not at all exhaustive of the types of data that a binary set can represent, and which can be utilized in accordance with the present principles. Moreover, it is to be further appreciated that given the teachings of the present principles provided herein, one of ordinary skill in this and related arts will contemplate these and other applications and data types to which the present principles may be applied, while maintaining the spirit of the present principles.

The present description illustrates the present principles. It will thus be appreciated that those skilled in the art will be able to devise various arrangements that, although not explicitly described or shown herein, embody the present principles and are included within its spirit and scope.

All examples and conditional language recited herein are intended for pedagogical purposes to aid the reader in understanding the present principles and the concepts contributed by the inventor(s) to furthering the art, and are to be construed as being without limitation to such specifically recited examples and conditions.

Moreover, all statements herein reciting principles, aspects, and embodiments of the present principles, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

Thus, for example, it will be appreciated by those skilled in the art that the block diagrams presented herein represent conceptual views of illustrative circuitry embodying the present principles. Similarly, it will be appreciated that any flow charts, flow diagrams, state transition diagrams, pseudocode, and the like represent various processes which may be substantially represented in computer readable media and so executed by a computer or processor, whether or not such computer or processor is explicitly shown.

The functions of the various elements shown in the figures may be provided through the use of dedicated hardware as well as hardware capable of executing software in association with appropriate software. When provided by a processor, the functions may be provided by a single dedicated processor, by a single shared processor, or by a plurality of individual processors, some of which may be shared. Moreover, explicit use of the term “processor” or “controller” should not be construed to refer exclusively to hardware capable of executing software, and may implicitly include, without limitation, digital signal processor (“DSP”) hardware, read-only memory (“ROM”) for storing software, random access memory (“RAM”), and non-volatile storage.

Other hardware, conventional and/or custom, may also be included. Similarly, any switches shown in the figures are conceptual only. Their function may be carried out through the operation of program logic, through dedicated logic, through the interaction of program control and dedicated logic, or even manually, the particular technique being selectable by the implementer as more specifically understood from the context.

In the claims hereof, any element expressed as a means for performing a specified function is intended to encompass any way of performing that function including, for example, a) a combination of circuit elements that performs that function or b) software in any form, including, therefore, firmware, microcode or the like, combined with appropriate circuitry for executing that software to perform the function. The present principles as defined by such claims reside in the fact that the functionalities provided by the various recited means are combined and brought together in the manner which the claims call for. It is thus regarded that any means that can provide those functionalities are equivalent to those shown herein.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

Also, as used herein, the words “picture” and “image” are used interchangeably and refer to a still image or a picture from a video sequence. As is known, a picture may be a frame or a field.

Additionally, as used herein, the word “signal” refers to indicating something to a corresponding decoder. For example, the encoder may signal one or more trees or sub-trees to re-use in decoding data such as, for example a binary set of data for indicating coefficient significance for one or more blocks in a picture. In this way, the same trees and/or sub-trees may be used at both the encoder side and the decoder side. Thus, for example, an encoder may transmit a set of trees and/or sub-trees to the decoder so that the decoder may use the same set of trees and/or sub-trees or, if the decoder already has the trees and/or sub-trees as well as others, then signaling may be used (without transmitting) to simply allow the decoder to know and select the trees and/or sub-trees. By avoiding transmission of any actual trees and/or sub-trees, a bit savings may be realized. It is to be appreciated that signaling may be accomplished in a variety of ways. For example, one or more syntax elements, flags, and so forth may be used to signal information to a corresponding decoder.

As noted above, the present principles are directed to methods and apparatus for reusing tree structures to encode and decode binary sets.

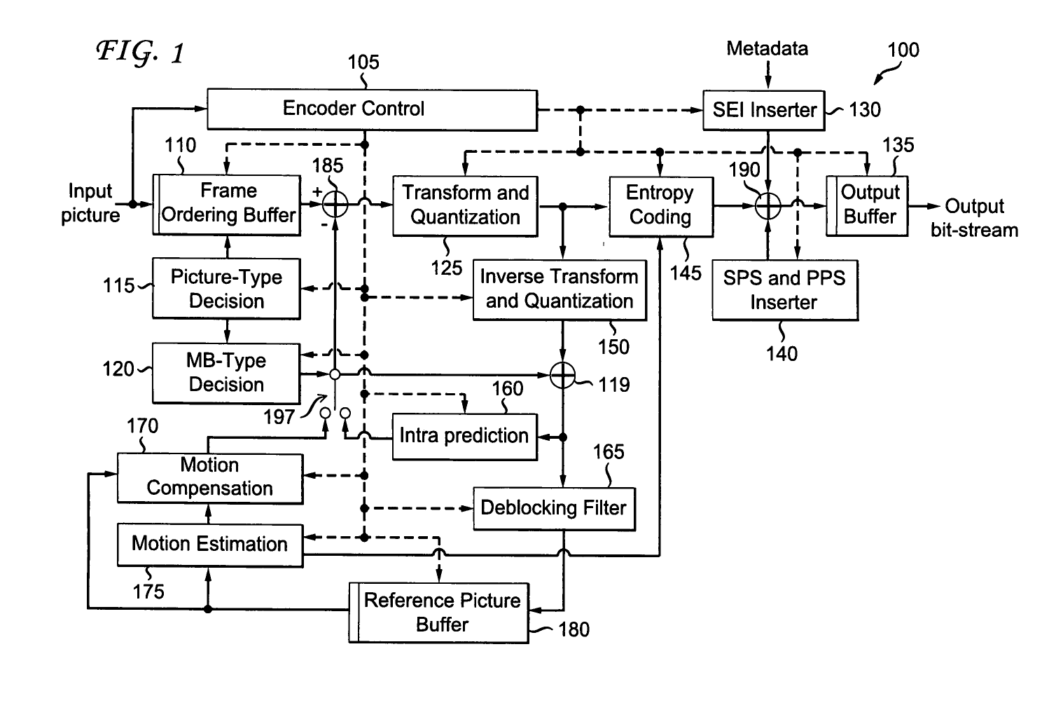

Turning to FIG. 1, an exemplary video encoder to which the present principles may be applied is indicated generally by the reference numeral 100. The video encoder 100 includes a frame ordering buffer 110 having an output in signal communication with a non-inverting input of a combiner 185. An output of the combiner 185 is connected in signal communication with a first input of a transformer and quantizer 125. An output of the transformer and quantizer 125 is connected in signal communication with a first input of an entropy coder 145 and a first input of an inverse transformer and inverse quantizer 150. An output of the entropy coder 145 is connected in signal communication with a first non-inverting input of a combiner 190. An output of the combiner 190 is connected in signal communication with a first input of an output buffer 135.

A first output of an encoder controller 105 is connected in signal communication with a second input of the frame ordering buffer 110, a second input of the inverse transformer and inverse quantizer 150, an input of a picture-type decision module 115, a first input of a macroblock-type (MB-type) decision module 120, a second input of an intra prediction module 160, a second input of a deblocking filter 165, a first input of a motion compensator 170, a first input of a motion estimator 175, and a second input of a reference picture buffer 180.

A second output of the encoder controller 105 is connected in signal communication with a first input of a Supplemental Enhancement Information (SEI) inserter 130, a second input of the transformer and quantizer 125, a second input of the entropy coder 145, a second input of the output buffer 135, and an input of the Sequence Parameter Set (SPS) and Picture Parameter Set (PPS) inserter 140.

An output of the SEI inserter 130 is connected in signal communication with a second non-inverting input of the combiner 190.

A first output of the picture-type decision module 115 is connected in signal communication with a third input of the frame ordering buffer 110. A second output of the picture-type decision module 115 is connected in signal communication with a second input of a macroblock-type decision module 120.

An output of the Sequence Parameter Set (SPS) and Picture Parameter Set (PPS) inserter 140 is connected in signal communication with a third non-inverting input of the combiner 190.

An output of the inverse quantizer and inverse transformer 150 is connected in signal communication with a first non-inverting input of a combiner 119. An output of the combiner 119 is connected in signal communication with a first input of the intra prediction module 160 and a first input of the deblocking filter 165. An output of the deblocking filter 165 is connected in signal communication with a first input of a reference picture buffer 180. An output of the reference picture buffer 180 is connected in signal communication with a second input of the motion estimator 175 and a third input of the motion compensator 170. A first output of the motion estimator 175 is connected in signal communication with a second input of the motion compensator 170. A second output of the motion estimator 175 is connected in signal communication with a third input of the entropy coder 145.

An output of the motion compensator 170 is connected in signal communication with a first input of a switch 197. An output of the intra prediction module 160 is connected in signal communication with a second input of the switch 197. An output of the macroblock-type decision module 120 is connected in signal communication with a third input of the switch 197. The third input of the switch 197 determines whether or not the “data” input of the switch (as compared to the control input, i.e., the third input) is to be provided by the motion compensator 170 or the intra prediction module 160. The output of the switch 197 is connected in signal communication with a second non-inverting input of the combiner 119 and an inverting input of the combiner 185.

A first input of the frame ordering buffer 110 and an input of the encoder controller 105 are available as inputs of the encoder 100, for receiving an input picture. Moreover, a second input of the Supplemental Enhancement Information (SEI) inserter 130 is available as an input of the encoder 100, for receiving metadata. An output of the output buffer 135 is available as an output of the encoder 100, for outputting a bitstream.

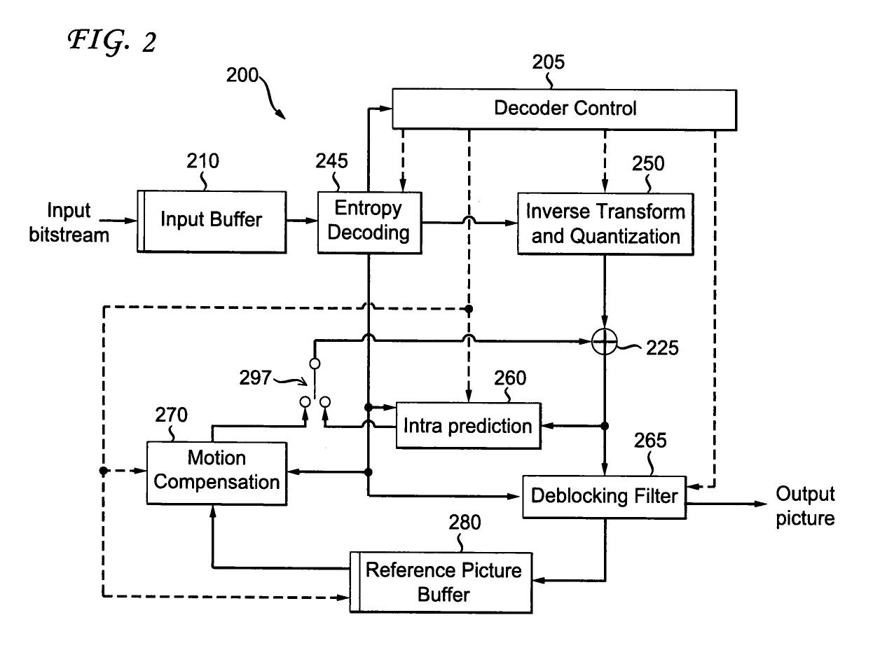

Turning to FIG. 2, an exemplary video decoder to which the present principles may be applied is indicated generally by the reference numeral 200. The video decoder 200 includes an input buffer 210 having an output connected in signal communication with a first input of an entropy decoder 245. A first output of the entropy decoder 245 is connected in signal communication with a first input of an inverse transformer and inverse quantizer 250. An output of the inverse transformer and inverse quantizer 250 is connected in signal communication with a second non-inverting input of a combiner 225. An output of the combiner 225 is connected in signal communication with a second input of a deblocking filter 265 and a first input of an intra prediction module 260. A second output of the deblocking filter 265 is connected in signal communication with a first input of a reference picture buffer 280. An output of the reference picture buffer 280 is connected in signal communication with a second input of a motion compensator 270.

A second output of the entropy decoder 245 is connected in signal communication with a third input of the motion compensator 270, a first input of the deblocking filter 265, and a third input of the intra predictor 260. A third output of the entropy decoder 245 is connected in signal communication with an input of a decoder controller 205. A first output of the decoder controller 205 is connected in signal communication with a second input of the entropy decoder 245. A second output of the decoder controller 205 is connected in signal communication with a second input of the inverse transformer and inverse quantizer 250. A third output of the decoder controller 205 is connected in signal communication with a third input of the deblocking filter 265. A fourth output of the decoder controller 205 is connected in signal communication with a second input of the intra prediction module 260, a first input of the motion compensator 270, and a second input of the reference picture buffer 280.

An output of the motion compensator 270 is connected in signal communication with a first input of a switch 297. An output of the intra prediction module 260 is connected in signal communication with a second input of the switch 297. An output of the switch 297 is connected in signal communication with a first non-inverting input of the combiner 225.

An input of the input buffer 210 is available as an input of the decoder 200, for receiving an input bitstream. A first output of the deblocking filter 265 is available as an output of the decoder 200, for outputting an output picture.

In the MPEG-4 AVC Standard, non-zero coefficient locations are encoded by means of a significance map. The significance map in the MPEG-4 AVC Standard works as follows. If the coded_block_flag indicates that a block has significant coefficients, then a binary-valued significance map is encoded. For each coefficient in scanning order, a one-bit symbol significant_coeff_flag is transmitted. If the significant_coeff_flag symbol is one, i.e., if a nonzero coefficient exists at this scanning position, then a further one-bit symbol last_significant_coeff_flag is sent. This symbol indicates if the current significant coefficient is the last one inside the block or if further significant coefficients follow. Note that the flags (significant_coeff_flag, last_significant_coeff_flag) for the last scanning position of a block are never transmitted. If the last scanning position is reached and the significance map encoding was not already terminated by a last_significant_coeff_flag with a value of one, then it is obvious that the last coefficient has to be significant.

Another way to indicate the significance is done by the so-called zero-trees. A tree is a widely-used data structure that emulates a hierarchical tree structure with a set of linked nodes. Moreover, a tree is an acyclic connected graph where each node has a set of zero or more children nodes, and at most one parent node.

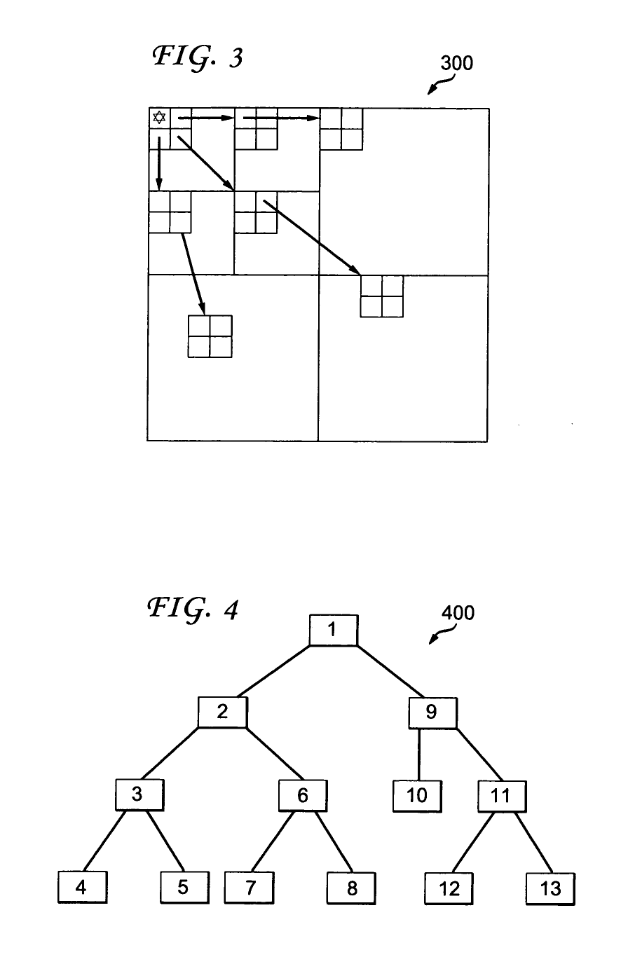

Examples of significance signaling with zero trees can be found in the wavelet transform for image compression. A tree-structure is used to convey the significance map. Turning to FIG. 3, an exemplary tree-structure to which the present principles may be applied is indicated generally by the reference numeral 300. Each of the small squares represents a transform coefficient. The root of the tree is represented by the small square that has the star included therein. The child-nodes are the neighboring coefficients. After that, the child-node relations are signaled with an arrow. As shown, each parent has as children, four other coefficients. The tree-structure 300 is only an example that shows these aforementioned relationships and how the tree is structured, but does not show the entire tree or parent-child relationships within the tree. In this case, each node of the tree is related to a coefficient, and the tree is constructed taking into account the spatial relationships between the wavelet transform coefficients in 2-D. Then, for every node, a 0 or a 1 is sent. A value/symbol of 0 indicates that the coefficient at a particular node in the tree as well as all the coefficients below that coefficient in the tree are zero. In this way, many zero coefficients are encoded with only one symbol. When there are many zeros, such an approach attains a good compression ratio.

A different type of tree is the binary-tree, which is a simple yet efficient kind of tree. In a first prior art approach, the tree is used to describe coefficient positions. In such a case, each leaf of the tree can be related to a transform coefficient, while the internal nodes of the tree are not related to any coefficient. Then, the encoding is similar to the previous case, i.e., when all the coefficients below a node are zero, then a “0” can indicate that situation, so there is no need to go below that node and explicitly indicate the significance/zero value of each “subsequent” coefficient. The present principles are directed to this type of tree.

The probability of a coefficient being significant depends on many factors that the prior art approaches do not properly consider. For example, there is a spatial correlation between the significance of coefficients. Moreover, the statistical properties of the coefficients of the lower frequencies are different from the statistical properties of the coefficients of the higher frequencies. Further, the significance map of different residue blocks can be very different. Therefore, using a single data-structure and encoding process is not enough to capture all this variability.

It has been proposed to use several trees and sub-trees to better adapt to the variability of the significance map (or any binary set). For each significance map, a selection is made of the best tree or combination of sub-trees that are to be used to encode the map. The use of transforms, groupings, flipping signs and other operations that exploit the statistical properties and correlation among the values of the leaves is also known and the use of these operations in the trees, sub-trees or parts thereof has also been proposed.

Video coding techniques are improving performance by increasing the prediction and transform sizes. These large sizes have an impact on the requirements of the tree structures. To simplify the requirements of the tree structures, we describe herein methods and apparatus for the use of recursive trees, in which a tree or part of a tree is reused to encode different parts of a binary set, such as, but not limited to, the significance map. Specifically, we re-use trees, or portions of the trees, in different areas of the binary set that have similar statistics. We adapt the tree structure so that a recursive algorithm is applied. This method reduces the number of probabilities required, while maintaining or even improving the coding performance of a full tree and keeping a very similar computational complexity.

In contrast, current video encoders use arithmetic coding for encoding symbols. Each symbol has a probability with an associated context. A tree-based method for encoding binary sets can adapt to statistics by entropy coding each symbol. One or more probabilities are associated to each node or branch between nodes. A drawback is that the number of probabilities increases with the size of the tree for the corresponding binary set. We propose to limit this increase by re-using the tree or sub-trees in different parts of the binary set. For example, 16×16 transform coefficients can re-use the zero-tree of 8×8 or sub-tree of 8×8. Thus, significant contexts associated with probabilities can be saved. From the point of view of efficiency, this reduction in complexity works when the re-use is limited to parts of binary sets with similar statistics. The present principles are beneficial when a larger transform is used to improve the coding efficiency, especially for high definition (HD) video.

In the zero-tree structure for encoding binary sets (such as, for example, the significance map of the transformed coefficients), the leaves are given the binary value of an element in the set. Therefore, there is a one-to-one relation between the value of each leaf and each element in the binary set. The significance map of the residue coefficients forms a binary set.

The value of a particular internal node is found by determining the value of the nodes below that particular internal node. In this way, the significance/binary value of each internal node is derived from the leaf nodes to the root node. Then, the tree is encoded by signaling the value of the nodes starting from the root node. Compression is attained because when a “0” is marked for a particular node that means that all the (“lower”) nodes below the particular node also are “0”, so there is no need to specifically signal the values for these lower nodes. Variants of this method exist.

### Example: Binary Tree

For purposes of clarity and illustration, we first explain the binary tree. A binary tree is a tree wherein each inner node has two child nodes, except for the leaf nodes that have no children. In the aforementioned first prior art approach, a binary tree was described for encoding significance maps.

Turning to FIG. 4, an exemplary binary tree to which the present principles may be applied is indicated generally by the reference numeral 400. The binary tree 400 includes nodes 1 through 13. The binary tree 400 has 6 inner nodes and 7 leave nodes. Node 1 is the root node. Nodes 2, 3, 6, 9 and 11 are internal nodes. Nodes 4, 5, 7, 8, 10, 12, and 13 are leaf nodes. The number in the node indicates the order in which the nodes are traversed. In this example, the order is depth-first. Of course, other orders are possible as readily contemplated by one of ordinary skill in this and related arts.

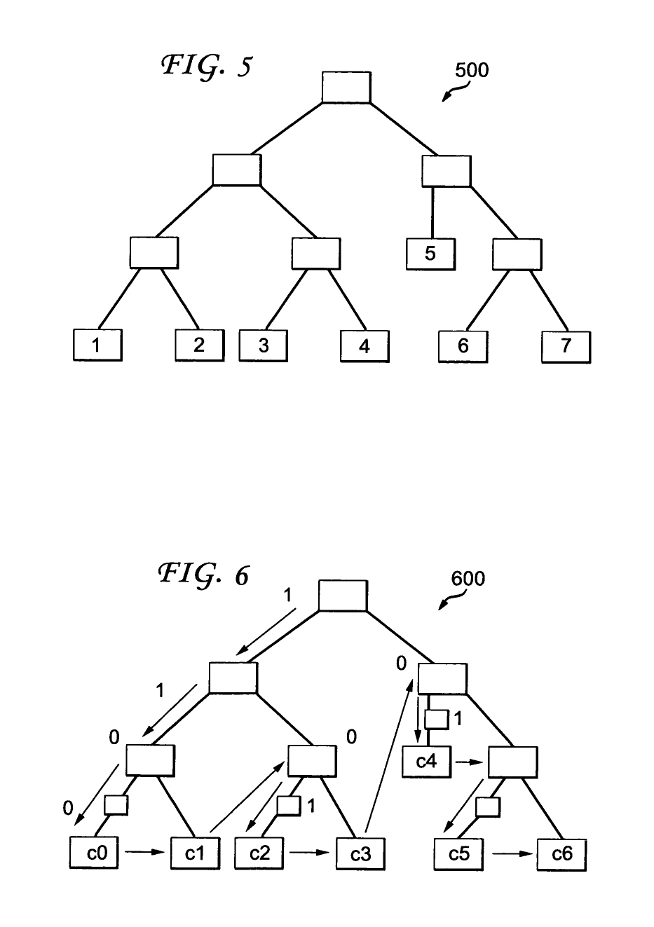

The binary set is mapped to the leaves of the tree. Turning to FIG. 5, an exemplary mapping of a binary set to the leaves of a binary tree is indicated generally by the reference numeral 500. A number in a leaf indicates the element of the binary set to which the leaf is linked. For instance, a significance map of 7 coefficients (which will be denoted by c0 to c6) can be encoded with this tree. The value of c0 is equal to “0” if the first coefficient is zero or is equal to “1” otherwise. The same applies to the rest of coefficients. The first coefficient significance is encoded using the leaf indicated by the reference numeral “1”, the second coefficient significance is encoded using the leaf indicated by the reference numeral “2”, and so on.

An example of how the encoding process is performed is described as follows. The encoding process starts from the root and follows the order in which the nodes are traversed (depth-first in this case). If the node is significant (meaning that both children are significant), then a “1” is encoded and the encoding process proceeds to the next node. If the node is non-significant (meaning that one of the children is non-significant), then a “0” is encoded, and then it is indicated whether the left or the right children is significant. This is done by encoding “1” if the left child is significant, and encoding “0” if the right child is significant.

A particular example is the following. Assume that the mapping to the leave nodes is done as described herein before. Also, assume that all coefficients are zero, except for c1, c2 and c4. Turning to FIG. 6, an exemplary encoding of a significance map using a binary zero-tree is indicated generally by the reference numeral 600. The encoding process is applied in a depth-first order. The inner nodes with “0” require sending a second symbol indicating which of the two children is significant. This is shown in FIG. 6 with a small square on the left branch with the corresponding symbol. The final symbols to encode in this map are “11000101”.

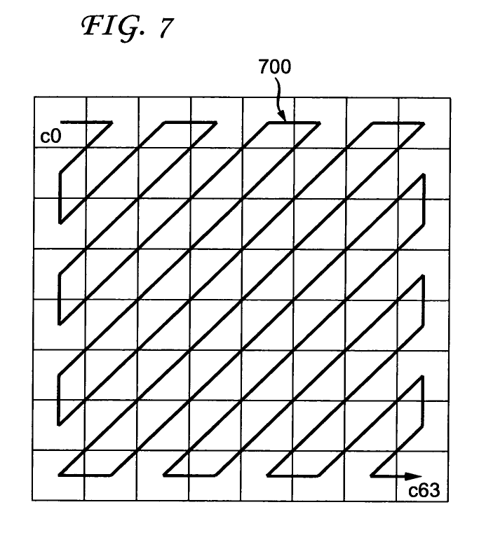

For a two-dimensional (2-D) transform, first the two dimensional coefficient set is mapped to a one dimensional set, and then each set is mapped to the leaves. Turning to FIG. 7, an exemplary mapping of two-dimensional (2-D) coefficients to a one dimensional (1-D) binary set is indicated generally by the reference numeral 700. In particular, the mapping 700 relates to a 2-D to 1-D mapping of the coefficients for an 8×8 transform. The map starts on the coefficient 0, c0, and follows the arrow until the last coefficient c63 at the bottom-right part.

### Reusing Tree Structures for Encoding and Decoding Binary Sets

Each symbol in the tree is entropy encoded with the corresponding probability. The entropy encoding can be done with an arithmetic coder. An encoder adapts well to the statistics and gives good performance when each probability is tracked and adapted to the content by the encoder and decoder. However, when the tree is large, like in the case of the significance map of a large transform, it can be too costly to store and track all the probabilities.

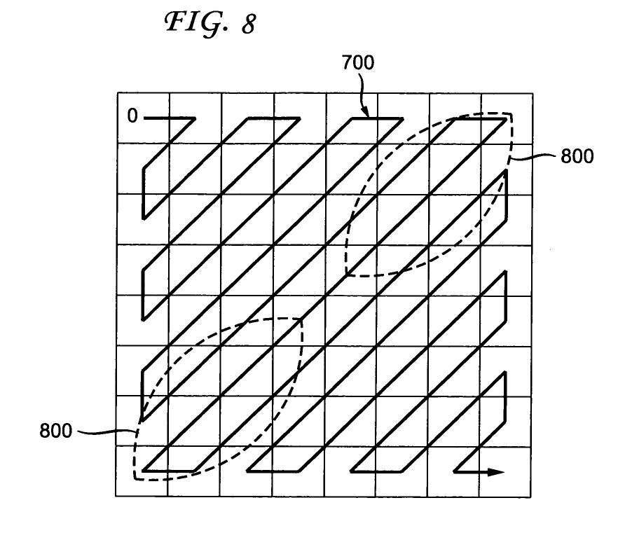

To alleviate this problem, we re-use tree structure and/or the associated probabilities for different parts of the binary set. In many cases, the re-use of a portion of a tree structure implicitly involves the re-use of any corresponding probabilities associated with the re-used portion. In this way, the most advantage can be obtained, since the re-using of the tree structure as well as the re-using of any associated probabilities results in a significant reduction in complexity, overhead, and so forth, as would be readily appreciated by one of ordinary skill in this and related arts. In one embodiment, in the case of the 8×8 transform, different parts of the significance map have similarities due to the frequencies in the vertical and horizontal directions being similar. There is a statistical symmetry between the top-right coefficients and the lower-left coefficients. In this case, the structure and probabilities can be reused on both parts. Turning to FIG. 8, parts of the exemplary mapping of FIG. 7 that can share the same tree in accordance with an embodiment of the present principles are indicated generally by the reference numeral 800. These parts 800, besides being indicated by reference numeral 800, are also indicated in FIG. 8 with a dashed ellipse-shaped line, whereas the remaining portions of mapping 700 are indicated by a solid line.

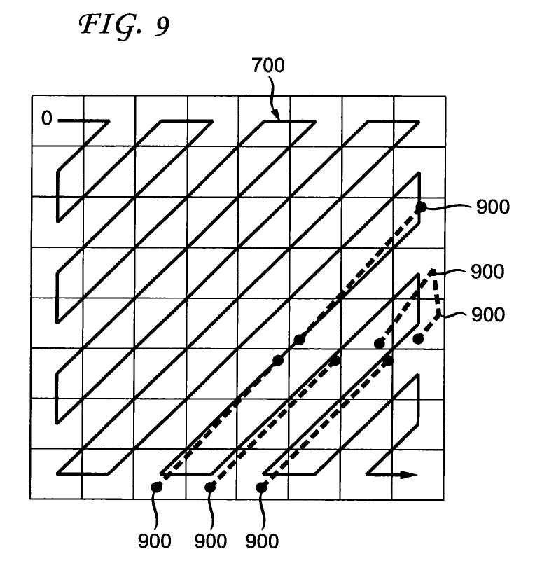

A significance map has other characteristics that can be exploited in accordance with the teachings of the present principles. Usually, the first few coefficients in the 1-D map have more probability of being significant and the correlation among them is high. On the other hand, the rest of the significance map is less probable of being significant and is less correlated. Also, the deeper in the tree, the fewer significant coefficients there are. Therefore, in another embodiment, these parts of the map are similar in the sense that they are almost always zeros. As a consequence, parts of the tree can be reused in those areas without damaging performance and while saving memory complexity. Turning to FIG. 9, other parts of the exemplary mapping of FIG. 7 that can share the same tree structure and probabilities in accordance with an embodiment of the present principles are indicated generally by the reference numeral 900. These parts 900, besides being indicated by reference numeral 900, are also indicated in FIG. 9 with a dashed lines, whereas the remaining portions of mapping 700 are indicated by a solid line.

It is to be appreciated that the similarity that can be exploited by the present principles to reuse one or more portions of previously used tree structure can be based on, for example, one or more similarity metrics. For example, applicable thresholds for judging similarity are readily contemplated by one of ordinary skill in this and related arts, given the teachings of the present principles provided herein. In such a way, readily usable objective criteria may be used to readily identify similarities and thus exploit the same in accordance with the present principles.

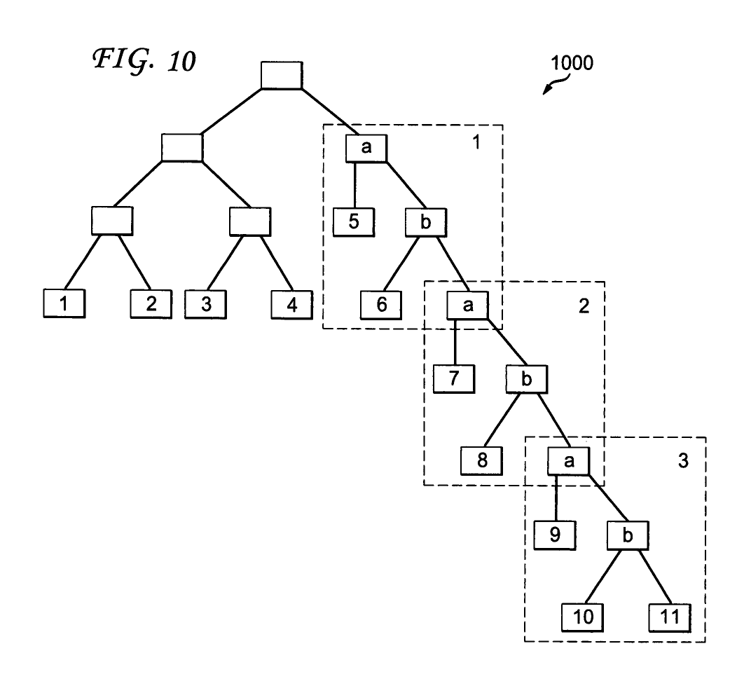

At least one exemplary implementation of the present principles will now be described. However, it is to be appreciated that such implementation is for illustrative purposes and the present principles are not limited to only the same. In the exemplary implementation, we presume the previous described situation, in which only the first few elements in the significance map have different statistics. Thus, for the following elements, a sub-tree of the tree is re-used. To do so, we propose a recursive tree, in which the last leaf of the tree connects with the root of the next tree (which is the same). In this way, the structure and probabilities are recursively reused. Turning to FIG. 10, an exemplary recursive binary tree in accordance with an embodiment of the present principles is indicated generally by the reference numeral 1000. There is a sub-tree of the tree that is used three times, as indicated by the three boxes depicted using dashed lines and respectively labeled to include therein the reference numerals “1”, “2”, and “3”. Thus, the same structure with the same inner nodes (a and b) is found three times (in the numbered dashed squares). The probabilities used to encode these leaves and the inner nodes can be the same.

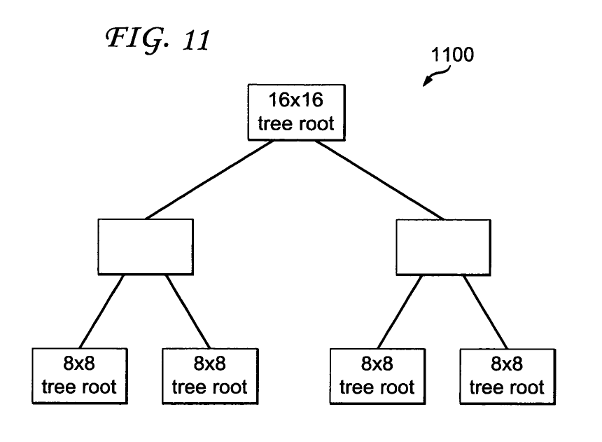

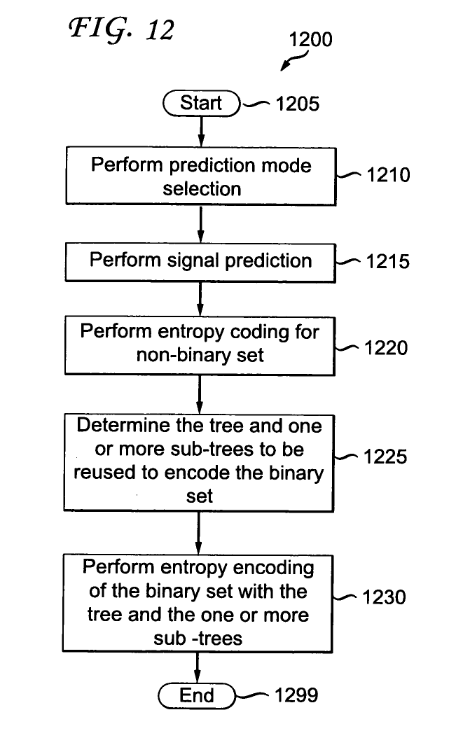

In another embodiment, we re-use a tree of smaller transforms for a larger transform. The coefficients of 16×16 transforms can be divided into four sets of 8×8 coefficients. For example, this can be done by putting the first coefficient in the first set, the second coefficient in the second set, the third coefficient in the third set, the fourth coefficient in the fourth set, the fifth coefficient in the first set again, and so on. Then, each of the four sets can use the tree for the 8×8 coefficients. Additionally, the four 8×8 trees can be put together in a single tree by a tree with four leaf nodes. Turning to FIG. 11, an exemplary re-use of smaller trees to create a larger tree for transform significance maps in accordance with an embodiment of the present principles is indicated generally by the reference numeral 1100.

This method works very well for cascaded transforms. A cascaded transform is a transform that is formed by sequentially concatenating two transforms. For example, a 16×16 transform can be obtained by applying four 8×8 transforms and then, a 2×2 transform on the DC components coming from the first transform. Then, the split of the 16×16 tree re-using the four 8×8 sub-trees comes naturally as follows: the coefficients of the first 8×8 transform plus one coefficient of the 2×2 transform would be a sub-tree, with a similar arrangement for the other 3 sub-trees.

It is to be appreciated that some of the methods described hereinafter refer to binary sets of data and non-binary sets of data. With respect to video data as one illustrative example, such sets of data can result from a determination of which prediction is to be performed on a current block in a picture to be encoded or decoded. In such a case, the binary set of data can be encoded or decoded using one method, while the non-binary set of data can be encoded or decoded using another method. It is the binary set of data in such a case to which the present principles are directed.

Turning to FIG. 12, an exemplary method for reusing tree structures to encode a binary set in accordance with an embodiment of the present principles is indicated generally by the reference numeral 1200. The method 1200 includes a start block 1205 that passes control to a function block 1210. The function block 1210 performs a prediction mode selection, and passes control to a function block 1215. The function block 1215 signals a prediction (obtained using the prediction mode selected by function block 1210), and passes control to a function block 1220. The function block 1220 performs entropy coding for a non-binary set, and passes control to a function block 1225. The function block 1225 determines the tree and one or more sub-trees to be re-used to encode the binary set, and passes control to a function block 1230. The function block 1230 performs entropy coding of the binary set with the tree and the one or more sub-trees determined by function block 1225, and passes control to an end block 1299.

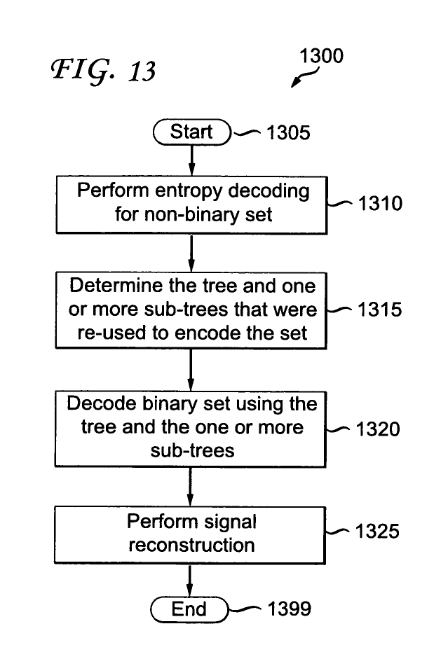

Turning to FIG. 13, an exemplary method for reusing tree structures to decode a binary set in accordance with an embodiment of the present principles is indicated generally by the reference numeral 1300. The method 1300 includes a start block 1305 that passes control to a function block 1310. The function block 1310 performs entropy decoding for a non-binary set, and passes control to a function block 1315. The function block 1315 determines the tree and the one or more sub-trees that were (previously) re-used to encode the set, and passes control to a function block 1320. The function block 1320 decodes the binary set using the tree and the one or more sub-trees determined by function block 1315, and passes control to a function block 1325. The function block 1325 performs signal reconstruction, and passes control to an end block 1399.

It is to be appreciated that while the methods 1200 and 1300 of FIGS. 12 and 13, respectively, involve the use of one tree and one or more sub-trees (from the one tree), in other embodiments the present principles may involve more than one tree and one or more sub-trees of the more than one tree. Given the teachings of the present principles provided herein, one of ordinary skill in this and related arts will contemplate these and other variations of the present principles, while maintaining the spirit of the present principles.

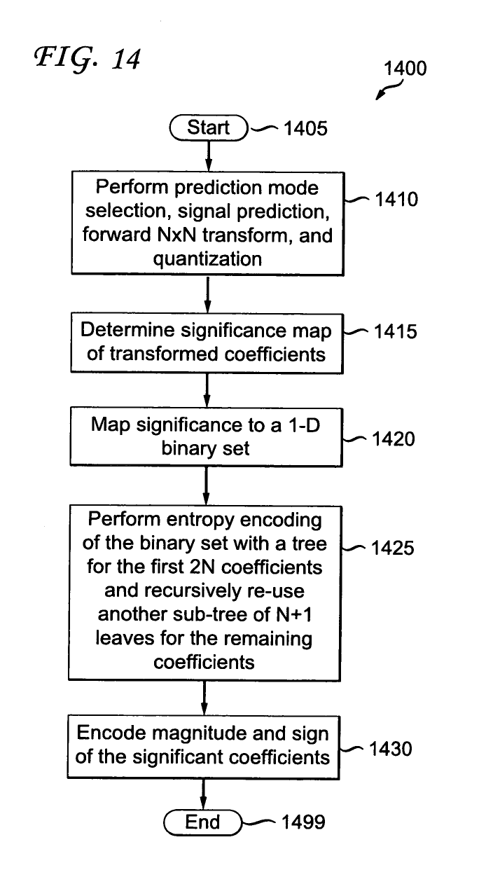

Turning to FIG. 14, another exemplary method for reusing tree structure to encode a binary set in accordance with an embodiment of the present principles is indicated generally by the reference numeral 1400. The method 1400 includes a start block 1405 that passes control to a function block 1410. The function block 1410 performs a prediction mode selection, signal prediction, forward N×N transform, and quantization, and passes control to a function block 1415. The function block 1415 determines a significance map of transformed coefficients, and passes control to a function block 1420. The function block 1420 maps significance to a one-dimensional (1-D) binary set, and passes control to a function block 1425. The function block 1425 performs entropy encoding of the binary set with a tree for the first 2N coefficients and recursively re-uses another sub-tree of N+1 leaves for the remaining coefficients, and passes control to a function block 1430. The function block 1430 encodes the magnitude and sign of the significant coefficients, and passes control to a function block 1499.

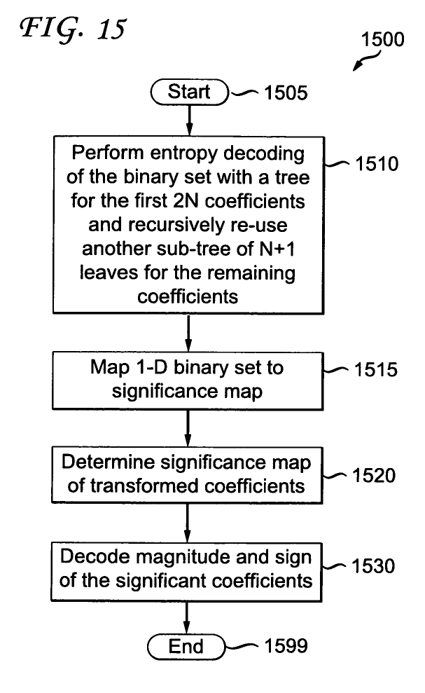

Turning to FIG. 15, another exemplary method for reusing tree structure to decode a binary set in accordance with an embodiment of the present principles is indicated generally by the reference numeral 1500. The method 1500 includes a start block 1505 that passes control to a function block 1510. The function block 1510 performs entropy decoding of the binary set with a tree for the first 2N coefficients and recursively re-uses another sub-tree of N+1 leaves for the remaining coefficients, and passes control to a function block 1515. The function block 1515 maps a one-dimensional (1-D) binary set to a significance map, and passes control to a function block 1520. The function block 1520 determines the significance map of transformed coefficients, and passes control to a function block 1530. The function block 1530 decodes the magnitude and sign of the significant coefficients, and passes control to an end block 1599.

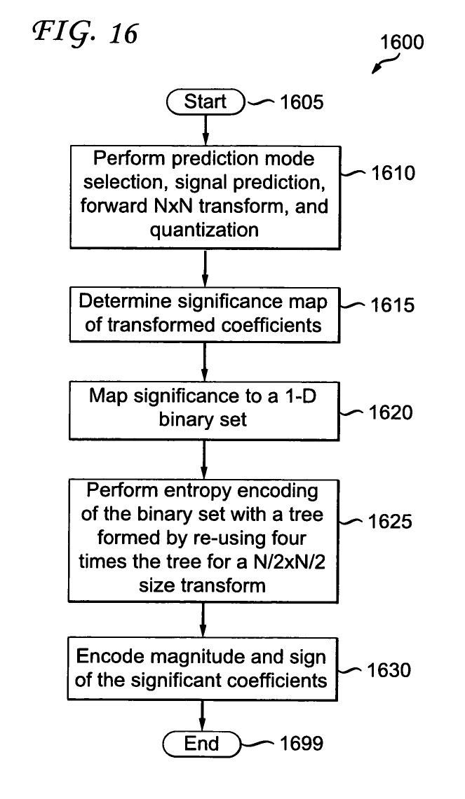

Turning to FIG. 16, still another exemplary method for reusing tree structure to encode a binary set in accordance with an embodiment of the present principles is indicated generally by the reference numeral 1600. The method 1600 includes a start block 1605 that passes control to a function block 1610. The function block 1610 performs a prediction mode selection, signal prediction, forward N×N transform, and quantization, and passes control to a function block 1615. The function block 1615 determines a significance map of transformed coefficients, and passes control to a function block 1620. The function block 1620 maps significance to a one-dimensional (1-D) binary set, and passes control to a function block 1625. The function block 1625 performs entropy encoding of the binary set with a tree formed by re-using four times the tree for a N/2×N/2 size transform, and passes control to a function block 1630. The function block 1630 encodes the magnitude and sign of the significant coefficients, and passes control to a function block 1699.

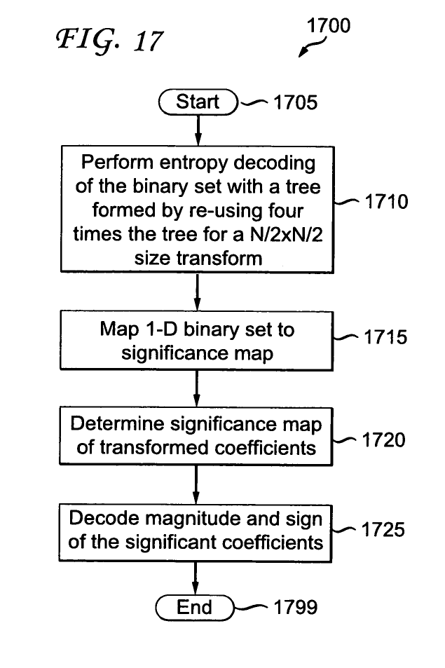

Turning to FIG. 17, still another exemplary method for reusing tree structure to decode a binary set in accordance with an embodiment of the present principles is indicated generally by the reference numeral 1700. The method 1700 includes a start block 1705 that passes control to a function block 1710. The function block 1710 performs entropy decoding of the binary set with a tree formed by re-using four times the tree for a N/2×N/2 size transform, and passes control to a function block 1715. The function block 1715 maps a one-dimensional (1-D) binary set to a significance map, and passes control to a function block 1720. The function block 1720 determines the significance map of transformed coefficients, and passes control to a function block 1730. The function block 1730 decodes the magnitude and sign of the significant coefficients, and passes control to an end block 1799.

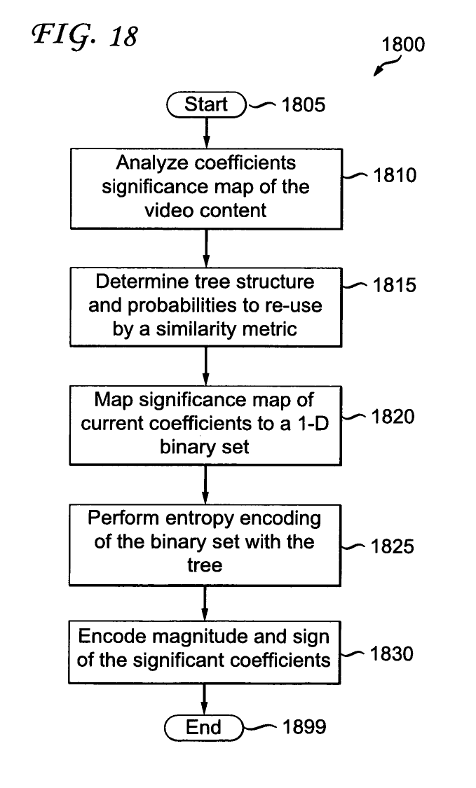

Turning to FIG. 18, yet another exemplary method for reusing tree structure to encode a binary set in accordance with an embodiment of the present principles is indicated generally by the reference numeral 1800. The method 1800 includes a start block 1805 that passes control to a function block 1810. The function block 1810 analyzes a coefficients significance map of video content, and passes control to a function block 1815. The function block 1815 determines a tree structure and probabilities to re-use by a similarity metric, and passes control to a function block 1820. The function block 1820 maps a significance map of current coefficients to a one-dimensional (1-D) binary set, and passes control to a function block 1825. The function block 1825 performs entropy encoding of the binary set with the tree, and passes control to a function block 1830. The function block 1830 encodes the magnitude and sign of the significant coefficients, and passes control to a function block 1899.

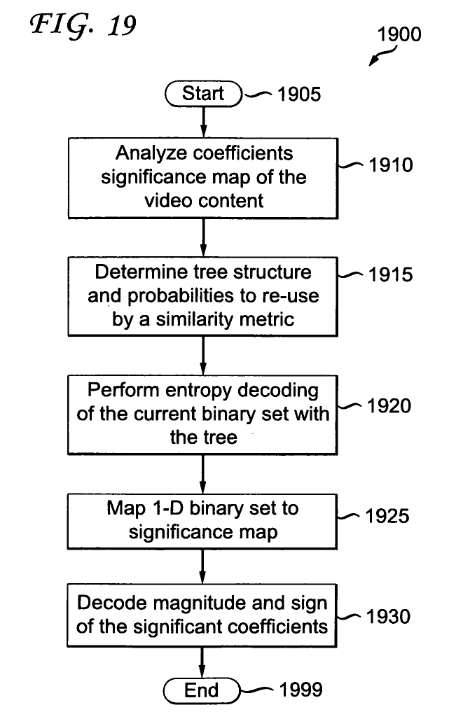

Turning to FIG. 19, yet another exemplary method for reusing tree structure to decode a binary set in accordance with an embodiment of the present principles is indicated generally by the reference numeral 1900. The method 1900 includes a start block 1905 that passes control to a function block 1910. The function block 1910 analyzes a coefficients significance map of video content, and passes control to a function block 1915. The function block 1915 determines a tree structure and probabilities to re-use by a similarity metric, and passes control to a function block 1920. The function block 1920 performs entropy decoding of the current binary set with the tree, and passes control to a function block 1925. The function block 1925 maps a one-dimensional (1-D) binary set to a significance map of the current coefficients, and passes control to a function block 1930. The function block 1930 decodes the magnitude and sign of the significant coefficients, and passes control to a function block 1999.

A description will now be given of some of the many attendant advantages/features of the present invention, some of which have been mentioned above. For example, one advantage/feature is an apparatus having an encoder for encoding a binary set of data using a tree structure. The encoder encodes a portion of the binary set using a portion of the tree structure and encodes another portion of the binary set by reusing at least some of the portion of the tree structure used to encode the portion of the binary set.

Another advantage/feature is the apparatus having the encoder as described above, wherein the at least some of the portion of the tree structure reused to encode the other portion of the binary set is recursively reused.

Yet another advantage/feature is the apparatus having the encoder as described above, wherein the binary set represents a significance of transform coefficients, and the significance of transform coefficients of a transform above a pre-specified size re-uses tree structure portions corresponding to transforms smaller than the pre-specified size.

Still another advantage/feature is the apparatus having the encoder as described above, wherein the apparatus is included in a video encoder.

Moreover, another advantage/feature is the apparatus having the encoder as described above, wherein a decision of which tree structure portions are to be reused is based on properties of the content to which the binary set corresponds.

Further, another advantage/feature is the apparatus having the encoder wherein a decision of which tree structure portions are to be reused is based on properties of the content to which the binary set corresponds as described above, wherein the properties of the content that are evaluated to render the decision are derived from a coefficient significance map.

Also, another advantage/feature is the apparatus having the encoder wherein a decision of which tree structure portions are to be reused is based on properties of the content to which the binary set corresponds as described above, wherein the decision is based on whether the properties are similar based on one or more similarity metrics.

These and other features and advantages of the present principles may be readily ascertained by one of ordinary skill in the pertinent art based on the teachings herein. It is to be understood that the teachings of the present principles may be implemented in various forms of hardware, software, firmware, special purpose processors, or combinations thereof.

Most preferably, the teachings of the present principles are implemented as a combination of hardware and software. Moreover, the software may be implemented as an application program tangibly embodied on a program storage unit. The application program may be uploaded to, and executed by, a machine comprising any suitable architecture. Preferably, the machine is implemented on a computer platform having hardware such as one or more central processing units (“CPU”), a random access memory (“RAM”), and input/output (“I/O”) interfaces. The computer platform may also include an operating system and microinstruction code. The various processes and functions described herein may be either part of the microinstruction code or part of the application program, or any combination thereof, which may be executed by a CPU. In addition, various other peripheral units may be connected to the computer platform such as an additional data storage unit and a printing unit.

It is to be further understood that, because some of the constituent system components and methods depicted in the accompanying drawings are preferably implemented in software, the actual connections between the system components or the process function blocks may differ depending upon the manner in which the present principles are programmed. Given the teachings herein, one of ordinary skill in the pertinent art will be able to contemplate these and similar implementations or configurations of the present principles.

Although the illustrative embodiments have been described herein with reference to the accompanying drawings, it is to be understood that the present principles is not limited to those precise embodiments, and that various changes and modifications may be effected therein by one of ordinary skill in the pertinent art without departing from the scope or spirit of the present principles. All such changes and modifications are intended to be included within the scope of the present principles as set forth in the appended claims.

1. An apparatus, comprising:
an encoder for encoding a binary set of data using a tree structure, wherein said encoder encodes a portion of the binary set using a portion of the tree structure and encodes another portion of the binary set by reusing at least some of the portion of the tree structure used to encode the portion of the binary set.

2. A method, comprising:
encoding a binary set of data using a tree structure, wherein said encoding step encodes a portion of the binary set using a portion of the tree structure and encodes another portion of the binary set by reusing at least some of the portion of the tree structure used to encode the portion of the binary set.

3. The method of claim 2, wherein the at least some of the portion of the tree structure reused to encode the other portion of the binary set is recursively reused.

4. The method of claim 2, wherein the binary set represents a significance of transform coefficients, and the significance of transform coefficients of a transform above a pre-specified size re-uses tree structure portions corresponding to transforms smaller than the pre-specified size.

5. The method of claim 2, wherein the apparatus is comprised in a video encoder.

6. The method of claim 2, wherein a decision of which tree structure portions are to be reused is based on properties of the content to which the binary set corresponds.

7. The method of claim 6, wherein the properties of the content that are evaluated to render the decision are derived from a coefficient significance map.

8. The method of claim 6, wherein the decision is based on whether the properties are similar based on one or more similarity metrics.

9. An apparatus, comprising:
a decoder for decoding a binary set of data using a tree structure, wherein said decoder decodes a portion of the binary set using a portion of the tree structure and decodes another portion of the binary set by reusing at least some of the portion of the tree structure used to decode the portion of the binary set.

10. A method, comprising:
decoding a binary set of data using a tree structure, wherein said decoding step decodes a portion of the binary set using a portion of the tree structure and decodes another portion of the binary set by reusing at least some of the portion of the tree structure used to decode the portion of the binary set.

11. The method of claim 10, wherein the at least some of the portion of the tree structure reused to decode the other portion of the binary set is recursively reused.

12. The method of claim 10, wherein the binary set represents a significance of transform coefficients, and the significance of transform coefficients of a transform above a pre-specified size re-uses tree structure portions corresponding to transforms smaller than the pre-specified size.

13. The method of claim 10, wherein the apparatus is comprised in a video decoder.

14. The method of claim 10, wherein a decision of which tree structure portions are to be reused is based on properties of the content to which the binary set corresponds.

15. The method of claim 14, wherein the properties of the content that are evaluated to render the decision are derived from a coefficient significance map.

16. The method of claim 14, wherein the decision is based on whether the properties are similar based on one or more similarity metrics.

17. A non-transitory, computer-readable storage media having video signal data encoded thereupon, comprising:
a binary set encoded of data using a tree structure, wherein a portion of the binary set is encoded using a portion of the tree structure and another portion of the binary set is encoded by reusing at least some of the portion of the tree structure used to encode the portion of the binary set.
